(19) United States
(12) Patent Application Publication
(10) Pub. No.: US 2026/0157214 A1
(43) Pub. Date: Jun. 4, 2026

(54) LASER COMPRESSION BONDING DEVICE AND METHOD

(71) Applicant: STATS ChipPAC Management Pte. Ltd., Singapore (SG)

(72) Inventors: JongChan PARK, Incheon (KR); HyungSuk MIN, Incheon (KR); TaeKeun LEE, Incheon (KR)

(21) Appl. No.: 19/405,435

(22) Filed: Dec. 2, 2025

(30) Foreign Application Priority Data
Dec. 4, 2024 (CN) 202411772585.9

(51) Int. Cl. H10W 72/00; B23K 1/00; B23K 1/005; B23K 3/047; B23K 101/40; B23K 103/00

(52) U.S. Cl. CPC H10W 72/07235; B23K 1/0016; B23K 1/0056; B23K 3/047; H10W 72/07141; H10W 72/07188; H10W 72/07232; B23K 2101/40; B23K 2103/56

(57) ABSTRACT

A laser compression bonding method comprises: placing a substrate on a carrier; preheating a compression head at least to a predetermined temperature; placing by the preheated compression head an electronic component on the substrate via a solder material; pressing the electronic component against the substrate by the preheated compression head; and irradiating to the carrier a laser beam from a laser source through the preheated compression head to bond the electronic component onto the substrate via the solder material.

### TECHNICAL FIELD

The present application generally relates to semiconductor technology, and more particularly, to a laser compression bonding device and method.

### BACKGROUND OF THE INVENTION

Laser compression bonding (LCB) or soldering processes have been used to replace conventional massive reflowing processes in forming semiconductor packages, because during the laser compression soldering process thermal stresses within the semiconductor packages can be reduced. However, LCB tools are generally made of transparent materials such as sapphire or the like, which have low thermal conductivities and high heat capacities. Heat may accumulate in the LCB tool during the bonding processes and may undesirably increase a temperature of the LCB tool, which affects the warpage in the semiconductor packages.

Several ways are proposed to cool down the LCB tools by dissipating the heat accumulated within the LCB tools to the external environment to reduce the warpage issue due to the heat accumulation. For example, a cooling device such as cooling air blower holes formed in an LCB tool is disclosed in Patent Publication No. KR1020140093086. The LCB tool is cooled down by air supplied through the cooling air blower holes during the bonding process. However, the cooling of LCB tools is not very effective due to the characteristics of the materials used in the LCB tools, e.g., the low thermal conductivity. Therefore, the temperature of the LCB tools may still increase as per the number of the LCB processes, which is not desired.

Therefore, a need exists for a new laser compression bonding device and method.

### SUMMARY OF THE INVENTION

An objective of the present application is to provide a laser compression bonding method and device to resolve an undesired temperature variation during the implementation of LCB processes.

According to an aspect of the present application, a laser compression bonding method is provided. The laser compression bonding method comprises: placing a substrate on a carrier; preheating a compression head at least to a predetermined temperature; placing by the preheated compression head an electronic component on the substrate via a solder material; pressing the electronic component against the substrate by the preheated compression head; and irradiating to the carrier a laser beam from a laser source through the preheated compression head to bond the electronic component onto the substrate via the solder material.

According to another aspect of the present application, a laser compression bonding device is provided. The device comprises: a carrier configured for placing a substrate, wherein an electronic component is disposed on the substrate via a solder material, a compression head configured for operably pressing the electronic component against the substrate via the solder material, a heating platform configured for placing a dummy assembly, and further configured for heating the compression head via the dummy assembly when the compression head is placed on the heating platform via the dummy assembly; and a laser source configured for irradiating to the heating platform a laser beam through the compression head to preheat the compression head at least to a predetermined temperature, and further configured for, after the compression head is preheated, irradiate to the carrier a laser beam through the preheated compression head to bond the electronic component onto the substrate via the solder material when the electronic component is pressed against the substrate.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 illustrates changes in temperature of an LCB tool and an electronic component held by a conventional LCB tool under different conditions.

FIGS. 2a to 2d illustrate a laser compression bonding method according to an embodiment of the present application.

FIGS. 3a to 3b illustrate a laser compression bonding device according to an embodiment of the present application.

FIGS. 4a to 4c illustrate changes in temperature of an LCB tool and an electronic component held by the LCB tool under different conditions according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As aforementioned, laser compression bonding (LCB) tools are usually made of transparent materials such as quartz, fused silica, sapphire or ZnSe, which have low thermal conductivities but high heat capacities. The thermal characteristics of the transparent materials increase difficulty in heating and cooling the LCB tools compared with conventional metal compression heads or tools. In particular, it is noted by the inventors of the present application that the LCB tools may undergo a slow but continuous temperature increase if multiple cycles of LCB processes are performed by the same LCB tool.

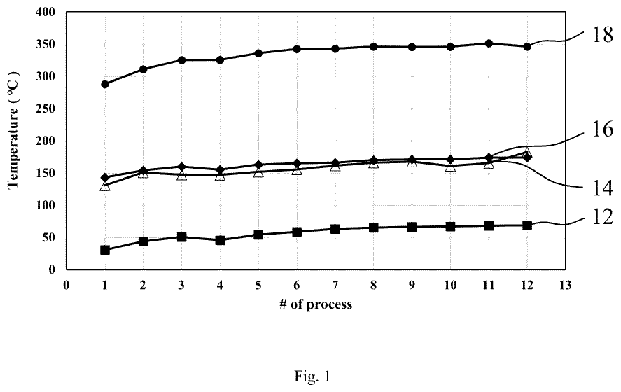

FIG. 1 illustrates changes in temperature of an LCB tool and an electronic component held by a conventional LCB tool under different conditions. As shown in FIG. 1, curve 12 depicts that the temperature at a surface of the LCB tool before bonding increases from about 30°C. to 68° C. after 12 cycles of LCB processes; curve 14 depicts that the peak temperature at the surface of the LCB tool during bonding increases from about 130° C. to about 180° C.; curve 16 depicts that the temperature of the electronic component before bonding increases from 143° C. to 174° C.; and curve 18 depicts that the peak temperature of the electronic component during bonding increases from 287° C. to 345° C. The significant temperature changes of the LCB tool and the electronic component may adversely affect the performance of the LCB tool especially the stability or uniformity of LCB processes implemented by the LCB tool, because the temperatures of the solder materials and the devices to be bonded together may increase as well, introducing undesired deviations into the bonding processes implemented by the LCB tools. Furthermore, the undesired temperature increases may also make the devices processed by the LCB tools easier to warp, which may lead to non-wetting or other issues.

In order to address the above issue, a laser compression bonding method is proposed to perform a of preheating the LCB tool such as the compression head, to a predetermined temperature, before the LCB processes implemented by the same LCB tool. In particular, the compression head can be heated to a saturated temperature, and thus can maintain the temperature of the LCB tool within a range which is acceptable to the following LCB processes. Different from conventional ways to cool down the LCB tools during the LCB processes, which face significant challenges in heat transferring and dissipation, the way of preheating the LCB tool is convenient to implement, and exhibits higher uniformity in temperature control.

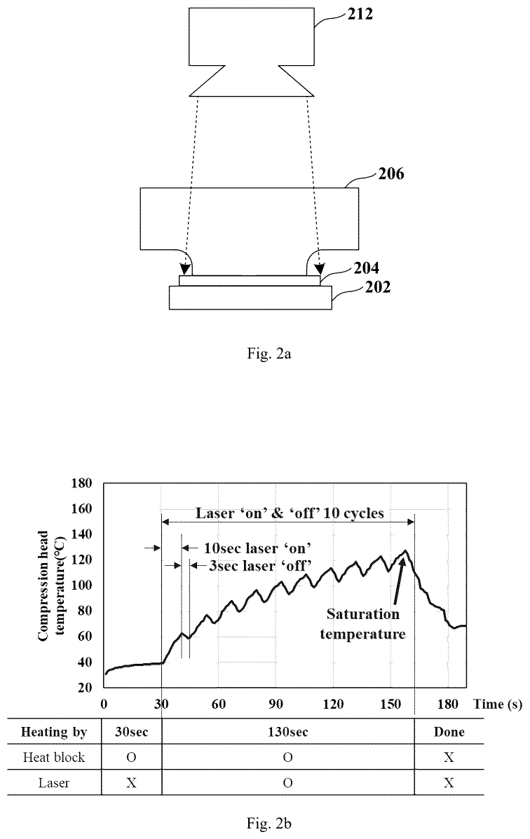

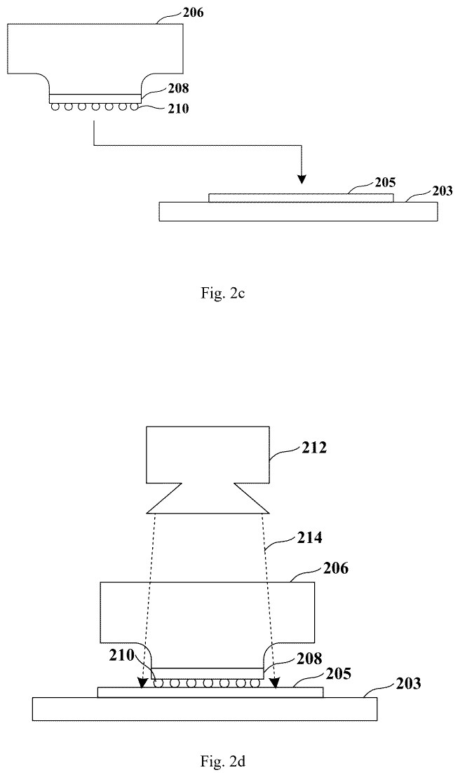

FIGS. 2a to 2d illustrate a laser compression bonding method according to an embodiment of the present application.

FIG. 2a illustrates a step of preheating a compression head to a predetermined temperature, before the compression head is used to perform LCB processes on various electronic components and substrates. As shown in FIG. 2a, a dummy assembly 204 may be placed on a heating platform 202 which is used to perform the preheating step. Further, the compression head 206 may be placed on the heating platform 202 and heated by the heating platform 202 via the dummy assembly 204. In some embodiments, the dummy assembly 204 may include a dummy substrate and a dummy electronic component or a metal coupon on the dummy substrate which is used to absorb energy of a laser beam. In other words, the dummy assembly 204 may mimic an electronic component and a substrate which are desired to be bonded together through a solder material such as a solder paste. In that case, the thermal condition such as heat transferring and heat capacity of the entire system including the compression head 202 and the dummy assembly 204 may be similar as that of the system including the compression head 202 and the electronic component and the substrate. In some other embodiments, the dummy assembly 204 may be formed as a single piece, as long as it has a thermal performance similar as the combination of the substrate and the electronic component to be bonded together. In some embodiments, the heating platform 202 may utilize a heating wire for the preheating, which can be embedded within the heating platform 202.

The laser compression bonding method is generally implemented by the compression head along with a laser source 212, which can emit a laser beam towards the electronic component and the substrate to be bonded together. Absorption of the optical energy of the laser beam actually results in the temperature increase of the compression head 206. That is, the laser source 212 can heat the compression head 206 as well. Accordingly, beside the heating platform 202, the laser source 212 may also be used as a heating device for the preheating of the compression head 206. In particular, the laser source 212 may irradiate a laser beam to the heating platform 202 through the compression head 206. The energy of the laser beam may be absorbed by the dummy assembly 204 and transferred into heat, which can then be transferred to the compression head 206. As such, the compression head 206 can be heated by both the laser source 212 and the heating platform 202.

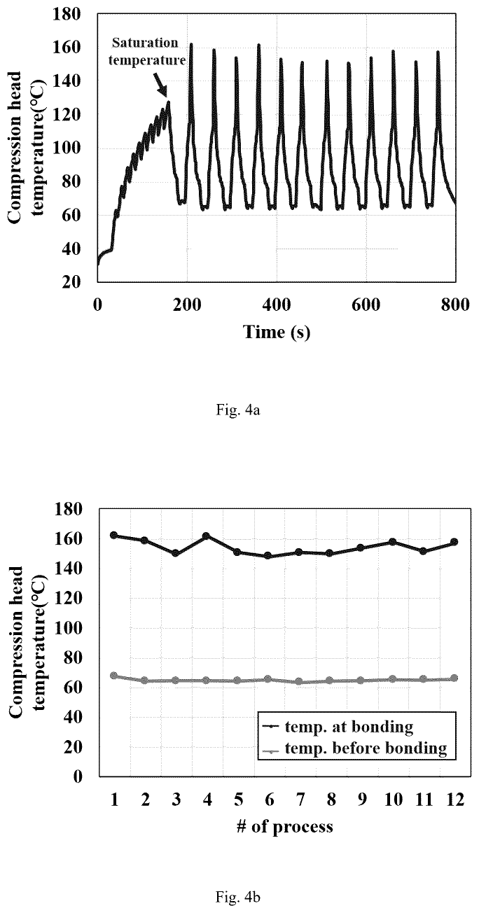

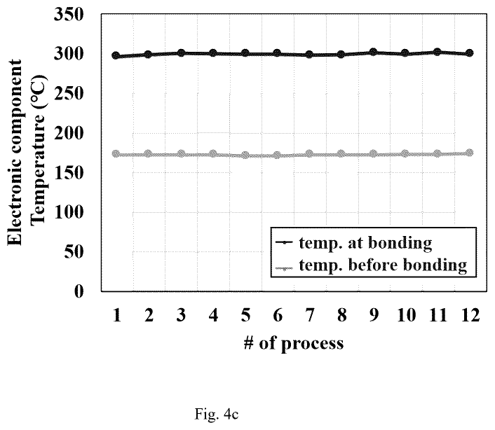

FIG. 2b illustrates a temperature variation of the compression head over time during the preheating step. Before the preheating step, the compression head is at approximately 30° C. which is close to room temperature. When the preheating begins, the compression head is heated by the heating platform 202 such as a heating block for a predetermined period such as 30 seconds, which increases the temperature of the compression head to 40° C. At this time, the laser source may not be turned on for the preheating. Following this, both of the platform heating and the laser heating may be performed to the compression head for another period. For example, the laser source may be repeatedly turned on to apply pulsed or cycled heating to the compression head. As shown in FIG. 2b, the process of pulsed or cycled heating can be repeated for 10 times or cycles. Specifically, the laser heating by the laser source is turned on for 10 seconds, followed by a 3-second interval where the laser source is turned off and only the platform heating by the heating platform is performed. After 10 cycles of this process, the temperature of the compression head may rise to the predetermined temperature, in this embodiment about 125° C., which is also the saturation temperature as identified in FIG. 2 b. The saturation temperature refers to a temperature at which the compression head may maintain when the same preheating condition is applied. That is to say, when the compression head reaches the saturation temperature, its temperature may not change substantially if more cycles of pulsed or cycled heating by the laser source is applied. Subsequently, both the heating block and the laser heating stop, and the compression head is allowed to cool down to a predetermined temperature such as 60° C. to 70° C., or preferably 65° C. The compression head may be maintained at the predetermined temperature before the start of each cycle of heating, as shown in FIG. 4a which will be elaborated later. As can be seen from FIG. 2b, the heating platform may continuously heat the compression head throughout the preheating process except the last cooling step, with laser heating intermittently applied during the procedure in this embodiment.

After the preheating step, the compression head may reach the desired temperature, and the laser compression bonding method continues. As shown in FIG. 2c, a substrate 205 may be placed on a carrier 203. Further, an electronic component 208 may be picked up by the compression head 206, for example, by being attached to a central portion of the compression head 206. A solder material 210 may be formed on a back surface of the electronic component 208, or alternatively formed on a front surface of the substrate 205. The compression head 206 may move to place the electronic component 208 on the substrate 205 via the solder material 210.

Next, as shown in FIG. 2d, the laser source 212 may be moved to a position above the compression head 206. When the electronic components 208 is in place on the substrate 205, the electronic component 208 can be pressed against the substrate 205 by the compression head 206. Furthermore, a laser beam 214 may be irradiated to the carrier 203 from the laser source 212. The laser beam 214 may pass through the compression head 206 to bond the electronic component 208 onto the substrate 205 via the solder material 210. Depending on the amount and composition of the solder material 210, the emission of the laser beam 214 may be configured or adjusted to supply sufficient energy to the solder material 210, which will not be elaborated in detail.

In some embodiments, the heating platform 202 shown in FIG. 2a may be used as the carrier 203 shown in FIG. 2d during the bonding process. For example, the carrier may include a heater or heating block which is operable to be turned on or off in the preheating process and the subsequent heating or bonding process, and accordingly the carrier may act as the heating platform in the preheating process by turning on the heater. In some other embodiments, the heating platform 202 may be a device different from the carrier 203.

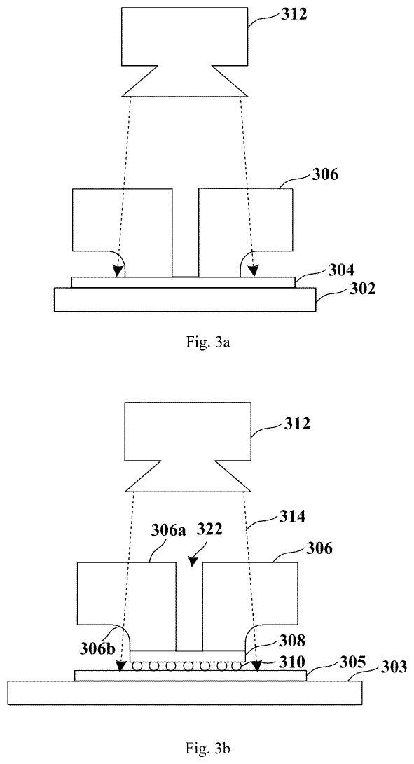

FIGS. 3a and 3b illustrate a laser compression bonding device according to an embodiment of the present application. In particular, as shown in FIG. 3a, the laser compression bonding device is operating in a preheating mode, to preheat a compression head to a saturation temperature by both a laser beam and a heating platform. As shown in FIG. 3b, the laser compression bonding device is in a bonding mode to generate the laser beam which may be used to bond one or more electronic components such as semiconductor chips onto a substrate such as a printed circuit board, an interposer, etc. by heating a solder material between the electronic components and the substrate. The solder material may be deposited onto either or both of the electronic components and the substrate prior to the bonding process, and then during the bonding process the solder material may be melted by energy delivered by the laser beam and later solidify as solder bumps to bond the electronic components with the substrate. Besides delivering the laser energy to the solder material, the laser compression bonding device also applies a pressure to the solder material to assist the bonding between the electronic components and the substrate.

In the preheating mode shown in FIG. 3a, a compression head 306 is placed on a heating platform 302 and heated by the heating platform 302 via a dummy assembly 304. Preferably, a laser beam which can be emitted from a laser source 312 may be directed to the heating platform 302 through the compression head 306 which can be made of a transparent material such as quartz, fused silica, sapphire or ZnSe, which have low thermal conductivities that are adverse to heat dissipation of heat accumulated in the compression head 306 during the laser compression bonding process. In some embodiments, the heating platform 302 may include temperature sensors to monitor the temperature in real-time and feed back to a control system (not shown) for accurate regulation of the preheating process.

Additionally, a material for the heating platform is critical as it needs to offer good thermal conductivity while remaining stable at high temperatures, resistant to deformation or degradation such as ceramic. The dummy assembly 304 plays an important role in the preheating process as well. It can be made of a material with a high thermal conductivity and high light absorption such as graphite or graphite coated copper, facilitating the transfer of heat from the heating platform 302 to the compression head 306 uniformly and consistently during the preheating process. The dummy assembly 304 is also designed to mimic the thermal characteristics of the materials used in the actual bonding process, ensuring that the compression head reaches the appropriate temperature before bonding. Furthermore, the dummy assembly 304 may be used for calibration and optimization of the heating platform and the laser source, for the preheating process.

In the bonding mode shown in FIG. 3b, the laser compression bonding device can be used to perform the bonding process. In particular, the laser compression bonding device includes a carrier 303 such as a carrier platform for placing a substrate 305, and the compression head 306 that has been preheated may hold and displace an electronic component 308 that is to be bonded onto the substrate 305. In particular, the compression head 306 may include a back surface on which the electronic component 308 is attached. The back surface may face towards the substrate 305 and the carrier 303 thereunder when the compression head 306 moves the electronic component 308 onto the substrate 305 via a solder material 310. In some examples, the electronic component 308 may have at its back side a first set of conductive patterns such as contact pads, and the substrate 305 may have at its front side a second set of conductive patterns such as contact pads which may have a layout identical to or similar as that of the first set of conductive patterns of the electronic component 308. The solder material 310 may be formed in advance on either or both of the two sets of conductive patterns, such that with the bonding process, the solder material 310 can bond the two sets of conductive patterns together and therefore electrically and mechanically connect the electronic component 308 with the substrate 305. In some embodiments, the electronic component 308 may be a semiconductor chip, while in some other embodiments, the electronic component 308 may be a semiconductor package or other similar devices or modules.

In the embodiment shown in FIG. 3b, the compression head 306 has a convex back surface. In particular, the back surface of the compression head 306 in a central portion 306a, i.e., where the electronic component 308 is attached, is lower and closer to the carrier 303, compared to the back surface of the compression head 306 in a peripheral portion 306b which surrounds the central portion 306a. In that case, when the compression head 306 presses the electronic component 308 against the substrate 305 via the solder material 310, the back surface in the central portion 306a may be in contact with the electronic component 308 while the back surface in the peripheral portion 306b may be farther away from the substrate 305 and the carrier 303, leaving enough space between the carrier 303 and the compression head 306 which can avoid undesired conflicts that may contaminate or even damage the compression head 306. However, it can be appreciated that the compression head 306 may have other shaped back surfaces. For example, the back surface of the compression head 306 may be flat, both in the central portion and in the peripheral portion.

In some embodiments, at least one through hole 322 may be formed in the compression head 306, which passes through the central portion 306a to apply a vacuum pressure to the electronic component 308 to hold the electronic component 308 firmly. For example, a vacuum source may be fluidly coupled to the through hole 322 to supply the vacuum pressure. The vacuum pressure may be applied during the movement of the electronic component 308 with the compression head 306, but may be released when the electronic component 308 is in place on the substrate 305, for example, during the bonding process.

The compression head 306 may be mechanically coupled to a driver or an actuator (not shown), which can move the compression head 306 automatically under the control of a controller, a host device or a server, or manually under the control of a user. Furthermore, when the electronic component 308 is placed on the substrate 305 via the solder material 310, the driver or the actuator may apply a force to the compression head 306, which in turn, generates a compression pressure at the solder material 310 to assist the bonding process.

Still referring to FIG. 3b, the laser source 312 can generate a laser beam 314 that is used to provide laser energy to reflow the solder material 310. In particular, the laser source 312 may be placed above the compression head 306 and facing towards the front surface of the compression head 306. During the laser compression bonding process, the laser beam 314 may be emitted from the laser source 312 towards the carrier 303 at least through the central portion 306a of the compression head 306 to heat the solder material 310. A sufficient amount of laser energy may be applied to the solder material 310 during the bonding process, to melt and reflow the solder material 310. When the laser source 312 is turned off, the melted solder material 310 may solidify into solder bumps between the substrate 305 and the electronic component 308. In this way, the electronic component 308 can be bonded onto the substrate 305 via the solder bumps after the bonding process.

FIGS. 4a to 4c illustrate changes in temperature of an LCB tool and an electronic component held by the LCB tool under different conditions according to an embodiment of the present application. The LCB tool has been preheated, for example, using the method shown in FIGS. 2a and 2b.

As shown in FIG. 4a, after the preheating process which heats the LCB tool such as the compression head to a saturation temperature, the compression head may cool down to 67° C. The temperature variation of the compression head from 0 to 200^{th} second corresponds to the preheating process of the compression head to the saturation temperature shown in FIG. 2b. Afterwards, 12 cycles of laser heating processes are performed from 200^{th} second to 800^{th} second. During each cycle of laser heating, the temperature of the compression head may first rise with the turning on of the laser source and then fall with the turning off of the laser source. However, the temperature variations within all the cycles are substantially the same.

FIGS. 4b and 4c illustrate a temperature change of the compression head and a temperature change of the electronic component, respectively. As can be seen, the compression head temperature before bonding has a variation of only 4.1° C., and the electronic component temperature before bonding has a variation of only 3° C. As such, the compression head temperature at the start of each bonding cycle can be maintained substantially the same, and all the electronic components processed by the laser compression bonding device can undergo similar temperature profiles, thereby increasing the reliability of the bonding processes.

As aforementioned, the compression head reaches to its saturation temperature after being heated by both the laser beam and the heating platform. The saturation temperature is influenced by the material and size of the compression head, as well as the heating method and heating parameters or some other factors. In the embodiment mentioned above, the saturation temperature for the compression head is around 120° C. to 130° C., or preferably 125° C. Accordingly, the temperature of the heating platform can be maintained at 120° C. to 130° C. or a slightly higher temperature. In an example, the laser source power is 140 W with a beam size of 19×17 mm² during the preheating process.

Specifically, the preheating process rapidly increases the compression head temperature to a higher stable state to reach thermal equilibrium. In contrast, the conventional LCB method does not employ the preheating step, resulting in that the compression head cannot achieve thermal equilibrium prior to the bonding process, leading to a continuous rise in temperature of the compression head during subsequent bonding cycles. Furthermore, a preheated compression head preserves more heat than a compression head that does not undergo such preheating process, which means the preheated compression head can better resist external temperature changes and maintain temperature stability. Also, the preheating process can improve heat distribution across the compression head, which can help to prevent undesired thermal stresses within the substrate processed by the compression head due to nonuniform heat distribution.

As aforementioned, the inventors further analyzed the temperature variation during the laser ‘on’ and ‘off’ cycles of the preheating step to identify when the temperature of a compression head can be saturated. Specifically, if the temperature increment from the conclusion of one cycle to the next cycle is smaller than 2%, or the temperature increment over three cycles is smaller than 5% (e.g., the temperature change over 130^{th} second to 160^{th} second in FIG. 2b), it may be concluded that the compression head and the electronic components before and during the bonding process can undergo the same heating profile or curve after the appropriate number of cycles of heating.

The discussion herein includes numerous illustrative figures that show various portions of a laser compression bonding device and a laser compression bonding method implemented by the same. For illustrative clarity, such figures do not show all aspects of each exemplary method. Any of the example methods provided herein may share any or all characteristics with any or all other methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A laser compression bonding method, comprising:
placing a substrate on a carrier;
preheating a compression head at least to a predetermined temperature;
placing by the preheated compression head an electronic component on the substrate via a solder material;
pressing the electronic component against the substrate by the preheated compression head; and
irradiating to the carrier a laser beam from a laser source through the preheated compression head to bond the electronic component onto the substrate via the solder material.

2. The laser compression bonding method of claim 1, wherein the step of preheating a compression head comprises:
placing the compression head on a heating platform via a dummy assembly; and
heating by the heating platform the compression head via the dummy assembly.

3. The laser compression bonding method of claim 2, wherein the step of preheating a compression head further comprises:
irradiating to the heating platform a laser beam from the laser source through the compression head.

4. The laser compression bonding method of claim 3, wherein the step of irradiating to the heating platform a laser beam from the laser source through the compression head further comprises:
irradiating to the heating platform the laser beam from the laser source for a predetermined number of cycles to preheat the compression head at least to the predetermined temperature.

5. The laser compression bonding method of claim 4, wherein the predetermined number of cycles are equal to or greater than 5 cycles.

6. The laser compression bonding method of claim 3, wherein the step of heating by the heating platform the compression head via the dummy assembly is started before and performed during the step of irradiating to the heating platform a laser beam from the laser source through the compression head is performed.

7. The laser compression bonding method of claim 3, wherein the dummy assembly comprises a dummy substrate and a dummy electronic component or a metal coupon on the dummy substrate which is configured to absorb energy of a laser beam.

8. The laser compression bonding method of claim 2, wherein the heating platform is the carrier, and the carrier comprises a heater which is operable to be turned on or off.

9. The laser compression bonding method of claim 1, wherein the predetermined temperature is 60 °C to 70 °C.

10. A laser compression bonding device, comprising:
a carrier configured for placing a substrate, wherein an electronic component is disposed on the substrate via a solder material;
a compression head configured for operably pressing the electronic component against the substrate via the solder material;
a heating platform configured for placing a dummy assembly, and further configured for heating the compression head via the dummy assembly when the compression head is placed on the heating platform via the dummy assembly; and
a laser source configured for irradiating to the heating platform a laser beam through the compression head to preheat the compression head at least to a predetermined temperature, and further configured for, after the compression head is preheated, irradiate to the carrier a laser beam through the preheated compression head to bond the electronic component onto the substrate via the solder material when the electronic component is pressed against the substrate.

11. The laser compression bonding device of claim 10, wherein the laser source is further configured for irradiating to the heating platform the laser beam through the compression head for a predetermined number of cycles to preheat the compression head at least to the predetermined temperature.

12. The laser compression bonding device of claim 11, wherein the predetermined number of cycles is equal to 10 cycles to preheat the compression head to 120 ° C. to 130 ° C., and the compression head is allowed to further cool down to the predetermined temperature.

13. The laser compression bonding device of claim 11, wherein the predetermined number of cycles is equal to or greater than 3 cycles, such that the compression head is heated to the predetermined temperature.

14. The laser compression bonding device of claim 10, wherein the laser source is further configured for irradiating to the heating platform the laser beam through the compression head after the heating platform starts to heat the compression head via the dummy assembly.

15. The laser compression bonding device of claim 10, wherein the dummy assembly comprises a dummy substrate and a dummy electronic component or a metal coupon on the dummy substrate which is configured to absorb energy of a laser beam.

16. The laser compression bonding device of claim 10, wherein the heating platform is the carrier, and the carrier comprises a heater which is operable to be turned on or off.

17. The laser compression bonding device of claim 10, wherein the predetermined temperature is 60 ° C. to 70 ° C.
